(19) United States
(12) Patent Application Publication
(10) Pub. No.: US 2014/0120717 A1
(43) Pub. Date: May 1, 2014

(54) Method of Semiconductor Integrated Circuit Fabrication

(71) Applicant: TAIWAN SEMICONDUCTOR MANUFACTURING, Hsin-Chu (TW)

(72) Inventors: Chien-Hua Huang, Pingzhen City (TW); Chung-Ju Lee, Hsinchu City (TW)

(73) Assignee: TAIWAN SEMICONDUCTOR MANUFACTURING COMPANY, LTD., Hsin-Chu (TW)

(21) Appl. No.: 13/666,694

(22) Filed: Nov. 1, 2012

(51) Int. Cl. H01L 21/768

(52) U.S. Cl. 438/653; 257/E21.584

(57) ABSTRACT

A method of fabricating a semiconductor integrated circuit (IC) is disclosed. The method includes providing a substrate. A metal-forming (MF) layer is deposited on the substrate. A radiation exposure process through a photomask is applied to the MF layer to form exposed regions and unexposed regions in the MF layer. The MF layer in the unexposed regions is removed while the MF layer in the exposed regions remains to form metal features. A dielectric layer is deposited to fill in regions between metal features.

### BACKGROUND

The semiconductor integrated circuit (IC) industry has experienced exponential growth. Technological advances in IC design and material have produced generations of ICs where each generation has smaller and more complex circuits than previous generation. In the course of IC evolution, functional density (i.e., the number of interconnected devices per chip area) has generally increased while geometry size (i.e., the smallest component (or line) that can be created using a fabrication process) has decreased.

This scaling down process generally provides benefits by increasing production efficiency and lowering associated costs. Such scaling down has also increased the complexity of IC processing and manufacturing. For these advances to be realized, similar developments in IC processing and manufacturing are needed. When a semiconductor device such as a metal-oxide-semiconductor field-effect transistor (MOSFET) is scaled down through various technology nodes, interconnects of conductive lines and associated dielectric materials that facilitate wiring between the transistors and other devices play a more important role in IC performance improvement. Although existing methods of fabricating IC devices have been generally adequate for their intended purposes, they have not been entirely satisfactory in all respects. It is desired to have improvements in this area.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flowchart of an example method for fabricating a semiconductor integrated circuit (IC) constructed according to various aspects of the present disclosure.

FIGS. 2 to 6 are cross-sectional views of an example semiconductor IC device at fabrication stages constructed according to the method of FIG. 1.

### DETAILED DESCRIPTION

It is to be understood that the following disclosure provides many different embodiments, or examples, for implementing different features of the disclosure. Specific examples of components and arrangements are described below to simplify the present disclosure. These are, of course, merely examples and are not intended to be limiting. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description that follows may include embodiments in which the first and second features are formed in direct contact, and may also include embodiments in which additional features may be formed between the first and second features, such that the first and second features may not be in direct contact.

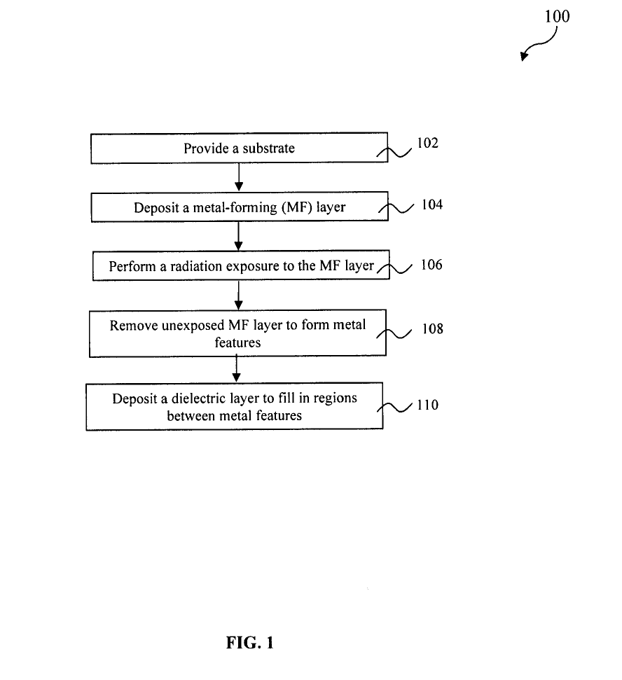

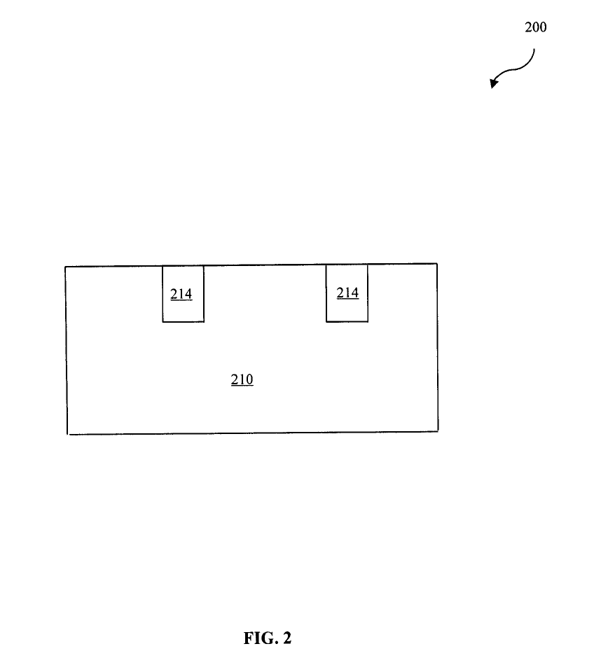

FIG. 1 is a flowchart of one embodiment of a method 100 of fabricating one or more semiconductor devices according to aspects of the present disclosure. The method 100 is discussed in detail below, with reference to a semiconductor device 200 shown in FIGS. 2 to 6 for the sake of example.

Referring also to FIG. 2, the method 100 begins at step 102 by providing a semiconductor substrate 210. The semiconductor substrate 210 includes silicon. Alternatively or additionally, the substrate 210 may include other elementary semiconductor such as germanium. The substrate 210 may also include a compound semiconductor such as silicon carbide, gallium arsenic, indium arsenide, and indium phosphide. The substrate 210 may include an alloy semiconductor such as silicon germanium, silicon germanium carbide, gallium arsenic phosphide, and gallium indium phosphide. In one embodiment, the substrate 210 includes an epitaxial layer. For example, the substrate 210 may have an epitaxial layer overlying a bulk semiconductor. Furthermore, the substrate 210 may include a semiconductor-on-insulator (SOI) structure. For example, the substrate 210 may include a buried oxide (BOX) layer formed by a process such as separation by implanted oxygen (SIMOX) or other suitable technique, such as wafer bonding and grinding.

The substrate 210 may also include various p-type doped regions and/or n-type doped regions, implemented by a process such as ion implantation and/or diffusion. Those doped regions include n-well, p-well, light doped region (LDD), heavily doped source and drain (S/D), and various channel doping profiles configured to form various integrated circuit (IC) devices, such as a complimentary metal-oxide-semiconductor field-effect transistor (CMOSFET), imaging sensor, and/or light emitting diode (LED). The substrate 210 may further include other functional features such as a resistor or a capacitor formed in and on the substrate.

The substrate 210 may also include various isolation features. The isolation features separate various device regions in the substrate 210. The isolation features include different structures formed by using different processing technologies. For example, the isolation features may include shallow trench isolation (STI) features. The formation of a STI may include etching a trench in the substrate 210 and filling in the trench with insulator materials such as silicon oxide, silicon nitride, or silicon oxynitride. The filled trench may have a multi-layer structure such as a thermal oxide liner layer with silicon nitride filling the trench. A chemical mechanical polishing (CMP) may be performed to polish back excessive insulator materials and planarize the top surface of the isolation features.

The substrate 210 may also include gate stacks formed by dielectric layers and electrode layers. The dielectric layers may include an interfacial layer (IL) and a high-k (HK) dielectric layer deposited by suitable techniques, such as chemical vapor deposition (CVD), atomic layer deposition (ALD), physical vapor deposition (PVD), thermal oxidation, combinations thereof, or other suitable techniques. The electrode layers may include a single layer or multi layers, such as metal layer, liner layer, wetting layer, and adhesion layer, formed by ALD, PVD, CVD, or other suitable process.

The substrate 210 may also include a plurality of inter-level dielectric (ILD) layers and conductive features integrated to form an interconnect structure configured to couple the various p-type and n-type doped regions and the other functional features (such as gate electrodes), resulting a functional integrated circuit. In one example, the substrate 210 may include a portion of the interconnect structure and the interconnect structure includes a multi-layer interconnect (MLI) structure and an ILD layer integrated with a MLI structure, providing an electrical routing to couple various devices in the substrate 210 to the input/output power and signals. The interconnect structure includes various metal lines, contacts and via features (or via plugs). The metal lines provide horizontal electrical routing. The contacts provide vertical connection between silicon substrate and metal lines while via features provide vertical connection between metal lines in different metal layers.

The ILD layers include a dielectric material layer, such as silicon oxide, silicon nitride, a dielectric material layer having a dielectric constant (k) lower than thermal silicon oxide (therefore referred to as low-k dielectric material layer), or other suitable dielectric material layer. A process of forming the ILD layer may utilize spin-on coating or chemical vapor deposition (CVD).

The substrate 210 also includes conductive features 214. The conductive features 214 include a portion of the interconnect structure. For example, the conductive features 214 include contacts, metal vias, or metal lines. In one embodiment, the conductive features 214 are further surrounded by a barrier layer to prevent diffusion and/or provide material adhesion. The conductive feature 214 may include aluminum (Al), copper (Cu) or tungsten (W). The barrier layer may include titanium nitride (TiN), tantalum nitride (TaN), tungsten nitride (WN), titanium silicon nitride (TiSiN) or tantalum silicon nitride (TaSiN). The conductive features 214 (and the barrier layer) may be formed by a procedure including lithography, etching and deposition. In another embodiment, the conductive features 214 include electrodes, capacitors, resistors or a portion of a resistor. Alternatively, the conductive features 214 may include doped regions (such as sources or drains), or gate electrodes. In another example, the conductive features 214 are silicide features disposed on respective sources, drains or gate electrodes. The silicide feature may be formed by a self-aligned silicide (salicide) technique.

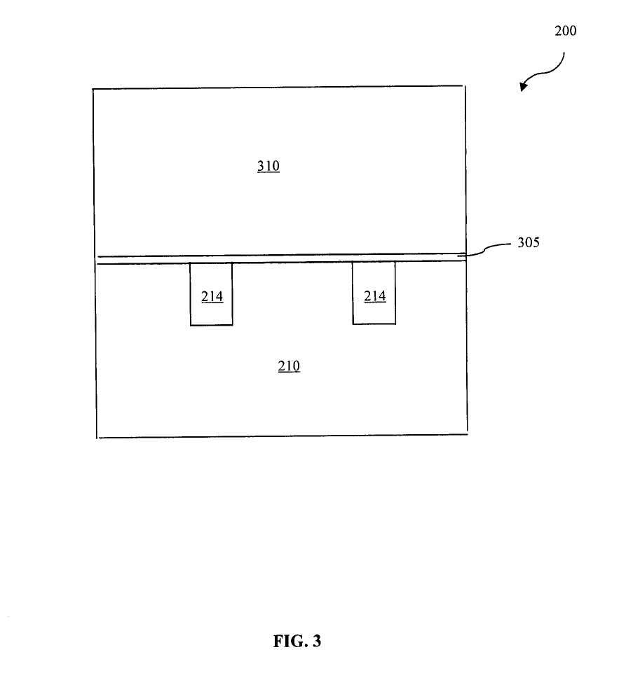

Referring to FIGS. 1 and 3, the method 100 proceeds to step 104 by depositing a metal-forming (MF) layer 310 on the substrate 210. In one embodiment, a barrier layer 305 is imposed between the substrate 210 and the MF layer 310. The barrier layer 305 includes silicon nitride, silicon carbide, or other appropriate materials. The barrier layer 305 may be deposited by atomic layer deposition (ALD), CVD, or any suitable method. The MF layer 310 includes photosensitive metal-containing materials, such as polydisalicylidene azomethines or other organometallic complex. Alternatively, the MF layer 310 includes high valence metals (alloys), such as copper (Cu), cobalt (Co), silver (Ag), cerium (Ce) and gold (Au), and their oxide, chloride, sulfide, fluoride, acetate and other metal compounds. The MF layer 310 may be deposited by any suitable method such as CVD, PVD, ALD, electrochemical plating (ECP), sputtering, spin-on coating and electroless plating.

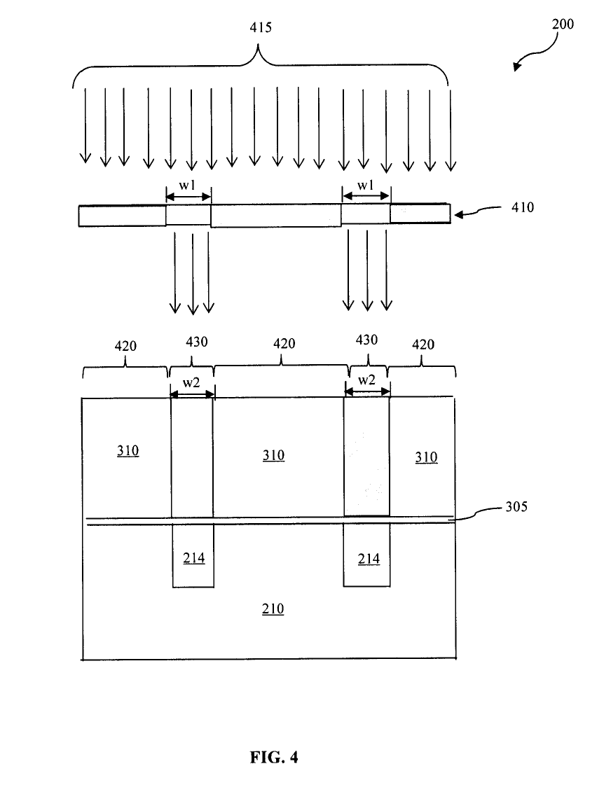

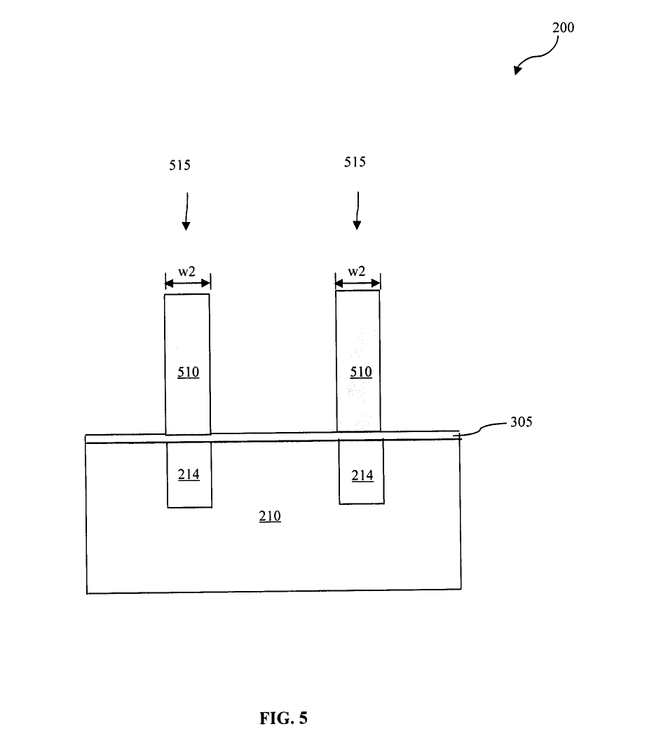

Referring to FIGS. 1 and 4, the method 100 proceeds to step 106 by performing a radiation exposure process to the MF layer by a lithography exposing tool. The exposing tool may utilize a deep ultraviolet (DUV), extreme ultraviolet (EUV), or X-ray radiation. In the present embodiment, the MF layer 310 is patterned by exposing it through a photomask 410 using an x-ray exposing tool to form an image pattern on it. A wavelength of an x-ray 415 is in a range from about 10-9 meters to about 10-12 meters. The photomask 410 includes openings with a first critical dimension (CD), labeled w1. The exposure process is performed under conditions including an atmosphere of inert gases or oxygen-free and a temperature in a range from about 10° C. to 500° C. The photomask 410 blocks some portions of the x-ray 415, thereby producing unexposed regions 420 in the MF layer 310. Meanwhile, the photomask 410 passes some portions of the x-ray 415, thereby producing exposed regions 430 in the MF layer 310. The exposed regions 430 have a second CD, labeled w2. The second CD w2 is substantial similar to the first CD w1. When the x-ray 415 projects onto the MF layer 310 in regions 430, it induces photoreduction of high valence metal compounds of the exposed MF layer 310, and results in converting metal compounds of the MF layer 310 from a high valence state to a low valence state, (for example, to a zero valence metal). After receiving the exposure, the MF layer 310 in the exposed regions 430 is referred to as a MF layer 510, discussed below with reference to FIG. 5.

Referring to FIGS. 1 and 5, the method 100 proceeds to step 108 by removing the MF layer 310 in the unexposed regions 420 while retaining the MF layer 510 to form metal features 515. The MF layer 310 in the unexposed regions 420 may be removed by an etch technique such as dry etch, wet etch, or combinations thereof. In one embodiment, a selective wet etch is performed to remove the MF layer 310 in the unexposed region 420. The wet etch process contains solutions of acetic acid, or ammonia, and/or other suitable etchant solutions. The wet etch process has a substantial selectivity with respect to the MF layer 510 such that the MF layer 510 remains fairly intact to form the metal features 515 with the second CD (w2). In this case, the CD (w2) of the metal features 515 is defined by the CD (w1) of the photomask 410 used by the x-ray exposure tool. By taking advantage of small wavelength of x-ray, a small pitch of metal features 515 can be achieved. And these metal features 515, with small CD, are formed by one photolithography process and one etch process.

In one embodiment, the metal features 515 are substantially aligned to the respective underlying conductive features 214. When the underlying conductive features 214 are metal lines of a different metal layer, the metal features 515 are also referred to as metal vias, via features or vias to provide vertical electrical routing between metal lines. In an alternative embodiment when the underlying conductive features 214 are source/drain features and/or gate electrodes, the metal features 515 are also referred to as metal contact, contact features or contacts to provide electrical routing between metal lines and semiconductor substrate.

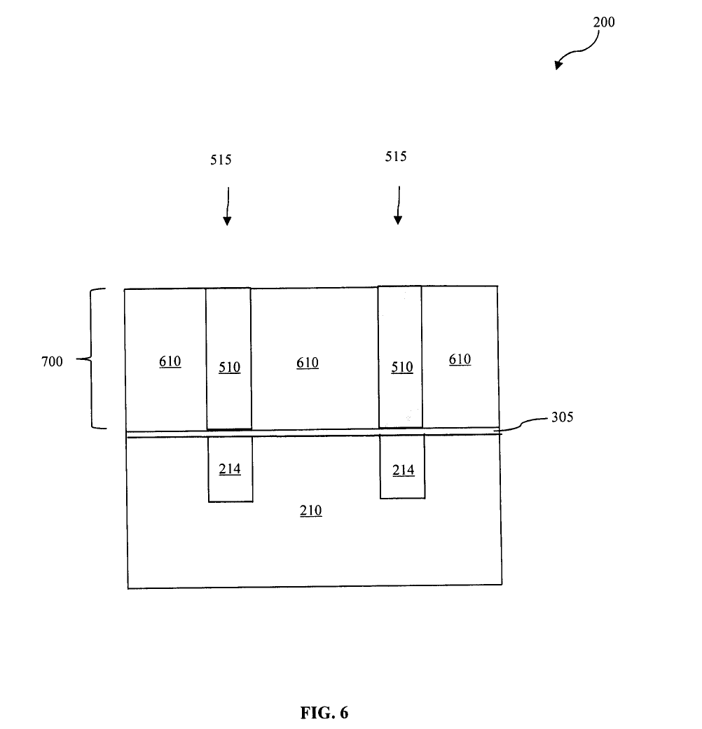

Referring to FIGS. 1 and 6, the method 100 proceeds to step 110 by depositing a dielectric material layer 610 to fill in regions between the metal features 515. The dielectric material layer 610 includes dielectric materials, such as silicon oxide, silicon nitride, a dielectric material having .a dielectric constant (k) lower than thermal silicon oxide (therefore referred to as low-k dielectric material layer), or other suitable dielectric material layer. In various examples, the low k dielectric material may include fluorinated silica glass (FSG), carbon doped silicon oxide, amorphous fluorinated carbon, Parylene, BCB (bis-benzocyclobutenes), SiLK (Dow Chemical, Midland, Mich.), polyimide, and/or other materials as examples. In another example, the low k dielectric material may include an extreme low k dielectric material (XLK). In yet another example, the low k dielectric material layer includes a porous version of an existing Dow Corning dielectric material called FOX (flowable oxide) which is based on hydrogen silsesquioxane. A process of forming the dielectric material layer 610 may utilize spin-on coating or CVD. In another embodiment, the dielectric material layer 610 is deposited by a spin-on dielectric (SOD) process to substantially fill in the regions between the metal features 515. In the present embodiment, the LK dielectric layer 610 is deposited to fill in the regions between the metal features 515.

Additionally, a chemical mechanical polishing (CMP) process is performed to remove excessive dielectric layer 610 and planarize the top surface of the dielectric layer 610 with the top surface of the metal feature 515. A layer formed by the metal features 515 separated by the dielectric layer 610 is referred to as a metal/dielectric section 700. In one embodiment, steps 104 to 110 are repeated to form new metal/dielectric sections over the metal/dielectric section 700.

Additional steps can be provided before, during, and after the method 100, and some of the steps described can be replaced, eliminated, or moved around for additional embodiments of the method 100.

Based on the above, the present disclosure offers methods for fabricating IC device. The method provides a direct patterning metal process to form a fairly small metal pitch by a one-photolithography-one-etch process scheme. The method also provides a non-dielectric-etch approach to form metal/dielectric interconnects, which minimizes process-induced damage, such as a damage by a dielectric etching.

The present disclosure provides many different embodiments of fabricating a semiconductor IC that provide one or more improvements over other existing approaches. In one embodiment, a method for fabricating a semiconductor integrated circuit (IC) includes providing a substrate, depositing a barrier layer on the substrate and depositing a metal-forming (MF) layer on the barrier layer. A radiation exposure process through a photomask is performed to the MF layer to form exposed regions and unexposed regions in the MF layer. The method also includes removing the MF layer in the unexposed regions while retaining the MF layer in the exposed region to form metal features and depositing a dielectric layer to fill in regions between metal features

In another embodiment, a method for fabricating a semiconductor IC includes providing a substrate, depositing a barrier layer on the substrate and depositing a metal-forming (MF) layer on the barrier layer. The MF layer includes high valence metal compounds. The method also includes performing a radiation exposure process through a photomask to the MF layer. A portion of the MF layer received the exposure converts to a lower valence metal. The method also includes performing a selective etch with respect to the lower valence metal to remove high valence metal compounds to form metal features. A dielectric layer is deposited to fill in regions between metal features.

In yet another embodiment, a method for fabricating a semiconductor IC includes providing a substrate, depositing a barrier layer on the substrate and depositing a metal-forming (MF) layer on the barrier layer. The MF layer includes photosensitive metal-containing polymers. The method also includes performing a radiation exposure process through a photomask to the MF layer, thereby the MF layer has exposed regions and unexposed regions. A critical dimension (CD) of an opening of the photomask defines each respective CD of the expose regions. The method also includes performing a selective etch to remove the MF layer in unexposed regions while retain the MF layer in exposed regions to form metal features. Thereby each CD of the metal features is defined by the respective CDs of the exposed regions. A dielectric layer is deposited to fill in regions between metal features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and /or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for fabricating a semiconductor integrated circuit (IC), the method comprising:
providing a substrate;
depositing a barrier layer on the substrate;
depositing a metal-forming (MF) layer on the barrier layer;
performing a radiation exposure process through a photomask to the MF layer to convert exposed regions of the MF layer into conducting features;
removing the MF layer in the unexposed regions; and
depositing a dielectric layer to fill in regions between the conducting features.

2. The method of claim 1, wherein the MF layer includes photosensitive metal-containing materials.

3. The method of claim 1, wherein the MF layer includes one or more high valence metal alloys from the group consisting of copper (Cu), cobalt (Co), silver (Ag), cerium (Ce) and gold (Au).

4. The method of claim 1, wherein the MF layer includes one or more high valence metal compounds from the group consisting of theirs oxide, chloride, sulfide, fluoride and acetate.

5. The method of claim 1, wherein the radiation exposure process includes an x-ray exposure process.

6. The method of claim 5, wherein the x-ray exposure process is performed in an oxygen-free atmosphere and a temperature range from about 10° C. to about 500° C.

7. The method of claim 5, wherein the x-ray exposure induces photoreductions in the exposed regions of the MF layer to convert high valence metal compounds to a lower valence metal.

8. The method of claim 7, wherein the high valence metal converts to zero valence metal.

9. The method of claim 1, wherein the MF layer in the unexposed regions is removed by a wet etch process.

10. The method of claim 9, wherein the wet etch process has a substantial etch selectivity with respect to the MF layer with a lower valence metal in the exposed regions.

11. The method of claim 10, wherein the MF layer in the exposed regions remain intact during the wet etch.

12. The method of claim 1, wherein a first critical dimension (w1) of a feature on the photomask defines a second critical dimension (w2) of a corresponding conducting feature.

13. The method of claim 1, wherein the dielectric layer includes a low-k material.

14. A method for fabricating a semiconductor integrated circuit (IC), the method comprising:
providing a substrate;
depositing a barrier layer on the substrate;
depositing a metal-forming (MF) layer on the barrier layer, wherein the MF layer includes high valence metal compounds;
performing a radiation exposure process through a photomask to the MF layer, wherein a portion of the MF layer received the exposure converts to a lower valence metal; performing a selective etch with respect to the lower valence metal to remove high valence metal compounds to form metal features; and
depositing a dielectric layer to fill in regions between metal features.

15. The method of claim 14, wherein the radiation exposure process includes an x-ray exposure process in an oxygen-free atmosphere and a temperature range from about 10° C. to about 500° C.

16. The method of claim 14, wherein the lower valence metal includes zero valence metal.

17. The method of claim 14, wherein a critical dimension (CD) of the metal feature is defined by each respective CD of an opening of the photomask.

18. A method for fabricating a semiconductor integrated circuit (IC), the method comprising:
providing a substrate;
depositing a barrier layer on the substrate;
depositing a metal-forming (MF) layer on the barrier layer, wherein the MF layer includes photosensitive metal-containing polymers;
performing a radiation exposure process through a photomask to the MF layer, wherein the MF layer has exposed regions and unexposed regions, wherein a critical dimension (CD) of an opening of the photomask defines each respective CDs of the expose regions;
performing a selective etch to remove the MF layer in unexposed regions while retain the MF layer in exposed regions to form metal features, wherein each CD of the metal features is defined by the respective CDs of the exposed regions; and
depositing a dielectric layer to fill in regions between metal features.

19. The method of claim 18, wherein the radiation exposure process includes x-ray exposure process in an oxygen-free atmosphere and a temperature range from about 10° C. to about 500° C.

20. The method of claim 18, wherein the selective etch includes a wet etch.
